(19) United States
(12) Patent Application Publication
(10) Pub. No.: US 2020/0274091 A1
(43) Pub. Date: Aug. 27, 2020

(54) DISPLAY PANEL AND METHOD FOR MANUFACTURING THEREOF, AND TERMINAL DEVICE USING SAME

(71) Applicant: Wuhan China Star Optoelectronics Semiconductor Display Technology Co., Ltd., Wuhan (CN)

(72) Inventor: Mian ZENG, Wuhan (CN)

(21) Appl. No.: 16/482,252

(22) PCT Filed: Apr. 11, 2019
(86) PCT No.: PCT/CN2019/082181

§ 371 Date: Jul. 31, 2019

(30) Foreign Application Priority Data
Feb. 27, 2019 (CN) 201910147199.3

(51) Int. Cl. H01L 51/52; H01L 51/56; H01L 27/32

(52) U.S. Cl. CPC H01L 51/5237; H01L 2227/323; H01L 27/326; H01L 51/56

(57) ABSTRACT

A display panel, a method for manufacturing the display panel, and a terminal device using the same are provided. A display panel includes a first region and a second region adjacent with each other, and a base layer, a functional layer, and an encapsulation layer disposed in sequence, wherein the functional layer is provided with a pixel array. The pixel array in the second region is provided with two or more light transmissive areas, and portions of the encapsulation layer corresponding to at least two of the light transmissive areas are respectively provided with a lens. A bottom surface of each of the lenses is planar and is disposed on the encapsulation layer, and an upper surface of each of the lenses is an outwardly convex curved surface.

### FIELD OF INVENTION

The present invention relates to a field of display technology, and more particularly, to a display panel and a method for manufacturing thereof, and a terminal device using the same.

### BACKGROUND OF INVENTION

It is known that with continuous development of the mobile phone industry, there has also been continuous development of mobile phone display technology, and functions on display screens have also increased. For example, a camera module has been widely used in display screens of current mobile phones.

Because of a structural setting, the camera module needs to be separated from the display screen of the current mobile phone, so that the available area for placing the display screen is reduced. At the same time, this kind of setting obviously deviates from the development trend of display screens of the current smartphones, which get bigger and bigger. As the camera module is an indispensable part of today's mobile phones, how to integrate the camera with the display screen to maximize a screen ratio is an urgent problem to be solved.

In this regard, the technical solution adopted by the industry usually is to design a front camera outside of the display screen, so the display screen needs to reserve the size to accommodate the front camera, which results that a normal display function cannot be performed in this part of the display area of the whole device. In the end, most mobile phones can only be shaped and cut, that is, the current popular mobile phones' “Screen Bangs”.

Therefore, the industry is currently in need of a related technical design of the screen camera to solve the problem that the full screen cannot be compatible with the front camera. However, there are difficulties in the screen camera technology, for example, how to improve transmittance of displays, uniformity of light transmission, and so on.

### SUMMARY OF INVENTION

One aspect of the present invention is to provide a display panel that adopts a novel surface structure design of panel such that a predetermined area thereof can perform a normal display function while the surface structure of panel can introduce a relatively large amount of incident light and simultaneously to achieve higher incident light transmittance.

The technical solution adopted by the present invention is as follows.

A display panel includes a first region and a second region adjacent with each other, and a base layer, a functional layer, and an encapsulation layer are disposed in sequence, wherein the functional layer is provided with a pixel array. The pixel array in the second region is provided with two or more light transmissive areas, and portions of the encapsulation layer corresponding to at least two of the light transmissive areas are respectively provided with a lens. A bottom surface of each of the lenses is planar and is disposed on the encapsulation layer, and an upper surface of each of the lenses is an outwardly convex curved surface.

Specifically, the first region can be a normal display area, for example, an AA area; and the second region can be a special function area, for example, a camera area.

Further, in different embodiments, the display panel is an active matrix organic light emitting diode (AMOLED) display panel, and the functional layer is a light emitting layer.

Further, in different embodiments, the light transmissive areas disposed in the pixel array are distributed in an array, a number of the lenses is corresponding to a number of the light transmissive areas, the lenses are arranged in an array, and the array of the lenses and the array of the light transmissive areas are arranged up and down. That is, a light transmissive area has a lens set above it.

Further, in different embodiments, each of the light transmissive areas is a cylindrical configuration, and the bottom surface of each of the lenses is circular, a diameter of the bottom surface of each of the lenses is equal to or greater than a diameter of a cross section of each of the light transmissive areas. Specifically, the diameter of the bottom surface of the lens can be greater than the diameter of the light transmissive area of 0-5 mm, which can be determined as needed, and is not limited.

Further, in different embodiments, each of the lenses is made of a photoresist. For example, the DQN type photoresist, and in other embodiments, the specific photoresist can be determined according to actual needs, and is not limited.

Further, in different embodiments, a melting point of the photoresist is less than 80 degrees.

Further, in different embodiments, a touch-controlling layer is further disposed on the encapsulation layer, and each of the lenses is disposed on an insulation layer of the touch-controlling layer.

Further, in different embodiments, a light-filtering layer is further disposed on the encapsulation layer, and each of the lenses is disposed on a planarization layer of the light-filtering layer.

Further, in different embodiments, a touch-controlling layer is disposed on the encapsulation layer, a light-filtering layer is disposed on the touch-controlling layer, and each of the lenses is disposed on a planarization layer of the light-filtering layer.

Further, another embodiment of the present invention provides a method of manufacturing the display panel according to the present invention including the following steps:

providing a base layer, providing a functional layer and an encapsulation layer on the base layer, wherein the functional layer is provided with a pixel array, and the pixel array is provided with two or more light transmissive areas;

coating a photoresist on portions of the encapsulation layer corresponding to at least two of the light transmissive areas, wherein the coated photoresist is subjected to ultraviolet exposure and development to obtain a cylindrical photoresist layer; and

heating the cylindrical photoresist layer to a molten state, wherein a liquid surface tension of the cylindrical photoresist layer transforms a surface cylindrical structure of the cylindrical photoresist layer into a smooth spherical crown structure of the cylindrical photoresist layer to form each of the lenses.

Further, another embodiment of the present invention provides a terminal device including a body. The display panel according to the present invention is disposed on the body, wherein a photosensitive device disposed on the body below the second region of the display panel.

Further, in different embodiments, the photosensitive device includes a camera module.

Compared with the current art, the beneficial effects of the present invention are as follows. The display panel of the present invention is provided with a lens array on its surface corresponding to an array of light transmissive areas therein. Since the convex curved surface of the lens can introduce more incident light relative to the planar surface, that is, the light that has been incident on the display panel not in the light transmissive area is refracted by the curved surface of the lens and entered to the light transmissive area below the lens array. Thereby, more incident light can be introduced into display panel without enlarging the original surface area of the light transmissive area, and then through the lens to enter below the display panel.

When the display panel according to the present invention is applied to a terminal device, if a photosensitive device, for example the camera module, is disposed under the panel, the camera module can obtain relatively more incident light, thereby ensuring image quality thereof. At the same time, the display panel can also perform a normal area display function, thereby implementing a “full-screen” display effect of the terminal device.

### DESCRIPTION OF DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic structural diagram of a display panel according to an embodiment of the present invention;

FIG. 2 is a partial cross-sectional view of the display panel shown in FIG. 1;

FIG. 3 is a cross-sectional view showing a partial structure of a display panel according to another embodiment of the present invention;

FIG. 4 is a cross-sectional view showing a partial structure of a display panel according to another embodiment of the present invention; and

FIG. 5 is a cross-sectional view showing a partial structure of a display panel according to another embodiment of the present invention.

### DETAILED DESCRIPTION OF PREFERRED EMBODIMENTS

The technical solutions of the display panel, the manufacturing method thereof, and the terminal device according to the present invention will be further described in detail below with reference to the accompanying drawings and embodiments.

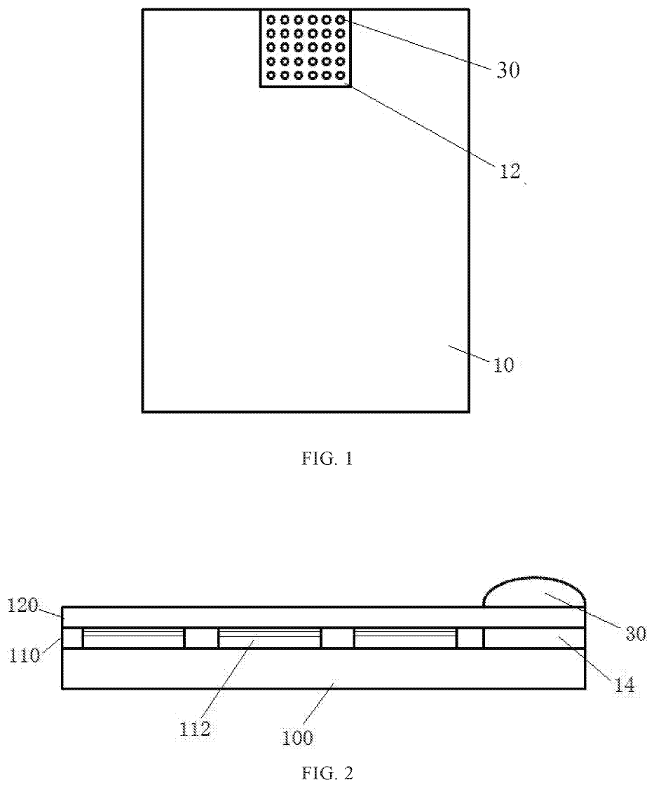

Referring to FIG. 1 and FIG. 2, an embodiment of the present invention provides a display panel including a base layer 100, a functional layer 110, and an encapsulation layer 120 disposed in sequence. A surface of the display panel is defined a first region 10 and a second region 12 adjacent with each other.

Specifically, the display panel is an active matrix organic light emitting diode (AMOLED) display panel, and the functional layer 110 is a light emitting layer. The light emitting layer 110 is provided with a pixel definition layer, the pixel definition layer is provided with a plurality of pixel structures 112, and those pixel structures 112 forms a pixel array.

A plurality of light transmissive areas 14 arranged in an array are further disposed on the pixel definition layer of the second region 12. The light transmissive area 14 is provided in the pixel array, and the light transmissive area 14 can be specifically formed by avoiding a metal layer of a pixel structure area, but is not limited thereto. In this way, the second region 12 can perform a normal area display function and incident light on the surface of the display panel can pass through the display panel and enter below the display panel by the light transmissive area 14.

Further, a lens 30 is disposed on the encapsulation layer 120 corresponding to each of the light transmissive areas 14 of the array of the light transmissive area. A bottom surface of each of the lenses 30 is planar and is disposed on the encapsulation layer 120, and an upper surface of each of the lenses 30 is an outwardly convex curved surface. Correspondingly, these lenses 30 correspond to the array of light transmissive area 14, and form a lens array.

The display panel of the present invention is provided with a lens array on its surface corresponding to an array of light transmissive areas therein. Because the convex curved surface of the lens can introduce more incident light relative to the planar surface, that is, the light that has been incident on the display panel not in the light transmissive area is as much as possible through the curved surface refraction into the light transmissive area. Thereby, more incident light is introduced into the original limited light transmissive area, and then passes through the light transmissive area to enter below the display panel.

Further, in different embodiments, each of the light transmissive areas 14 is a cylindrical configuration, the bottom surface of each of the lenses 30 is circular, a diameter of the bottom surface of each of the lenses 30 is equal to or greater than a diameter of a cross section of each of the light transmissive areas 14. Specifically, the diameter of the bottom surface of the lens 30 can be greater than the diameter of the light transmissive area of 0-5 mm, which can be determined as needed, and is not limited.

Each of the lenses 30 is made of a photoresist, preferably a melting point of the photoresist is less than 80 degrees. Specifically, the selected photoresist can be a DQN type photoresist. In other embodiments, the specific photoresist can be determined according to actual needs, and is not limited.

Further, the display panel of the present invention can have a variety of layered structures, and is not limited to the display panel structure disclosed in FIGS. 1 and 2. The encapsulation layer 120 can also be provided with a touch-controlling layer and/or a light-filtering layer thereon.

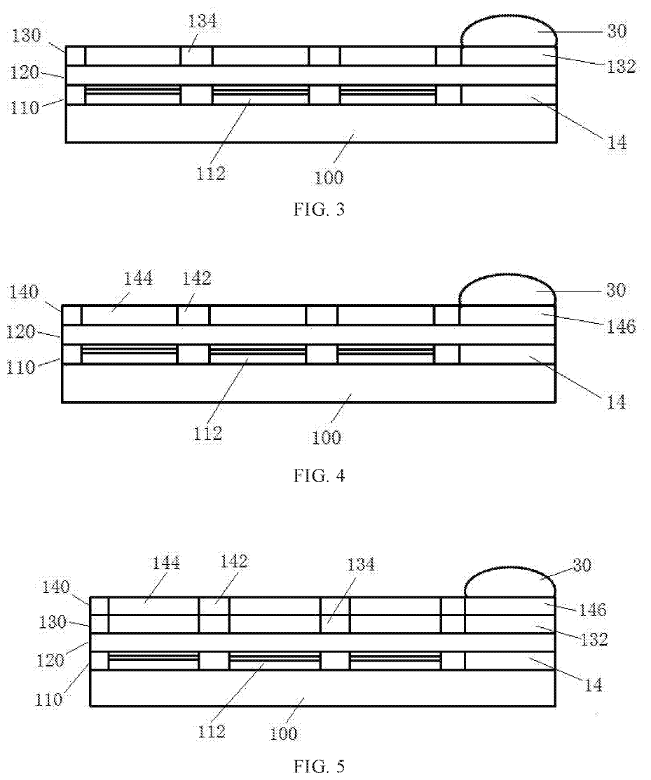

Referring to FIG. 3, which illustrates a layered structure of a display panel provided by another embodiment of the present invention. The touch-controlling layer 130 is disposed on the encapsulation layer 120. The touch-controlling layer 130 is provided with the insulation layer 132 and the touch-controlling electrode 134, wherein the lens 30 is disposed on the insulation layer 132.

Referring to FIG. 4, a layered structure of a display panel provided by another embodiment of the present invention is illustrated. The light-filtering layer 140 is disposed on the encapsulation layer 120. The light-filtering layer 140 is provided with a black matrix (BM) 142 and a color film 144, and the black matrix 142 separates the color film 144. Each color film 144 corresponds to the pixel 112 under it, and the color film corresponding to the light transmissive area 14 is replaced by a planarization layer (OC layer) 146. Accordingly, the lens 30 is disposed on the planarization layer 146.

Referring to FIG. 5, which illustrates a layered structure of a display panel according to another embodiment of the present invention. The encapsulation layer 120 is provided with the touch-controlling layer 130 and the light-filtering layer 140, and the lens is disposed on the planarization layer 146. The touch-controlling layer 130 and the light-filtering layer 140 are consistent with the structures disclosed above, and are not described herein again in order to avoid unnecessary repetition.

Further, another embodiment of the present invention provides a method of manufacturing the display panel according to the present invention, including the following steps:

providing a base layer, providing a functional layer and an encapsulation layer on the base layer, wherein the functional layer is provided with a pixel array, and the pixel array is provided with two or more light transmissive areas;

coating a photoresist on portions of the encapsulation layer corresponding to at least two of the light transmissive areas, wherein the coated photoresist is subjected to ultraviolet exposure and development to obtain a cylindrical photoresist layer; and

heating the cylindrical photoresist layer to a molten state, wherein a liquid surface tension of the cylindrical photoresist layer transforms a surface cylindrical structure of the cylindrical photoresist layer into a smooth spherical crown structure of the cylindrical photoresist layer to form each of the lenses.

In order to prevent the heat treatment of the photoresist structure from affecting the quality of the display panel underneath, it is preferable to use a photoresist having a lower melting point, so that the device in the functional layer disposing on the base layer is safer, such as a DQN type photoresist, but not limited to.

Further, another embodiment of the present invention provides a terminal device, including a body. The display panel according to the present invention is disposed on the body, and a photosensitive device is disposed on the body below the second region of the display panel. The photosensitive device can be a camera module, but not limited to.

The display panel of the present invention is provided with a lens array on its surface corresponding to an array of light transmissive areas therein. Because the convex curved surface of the lens can introduce more incident light relative to the planar surface, that is, the light that has been incident on the display panel not in the light transmissive area is refracted by the curved surface of the lens and entered to the light transmissive area below the lens array. Thereby, more incident light can be introduced into display panel without enlarging the original surface area of the light transmissive area, and then through the lens to enter below the display panel.

When the display panel according to the present invention is applied to a terminal device, if a photosensitive device, for example the camera module, is disposed under the panel, the camera module can obtain relatively more incident light, thereby ensuring image quality thereof. At the same time, the display panel can also perform a normal area display function, thereby implementing a “full-screen” display effect of the terminal device.

The technical scope of the present invention is not limited to the above description, a person skilled in the art can make various modifications and changes to the above embodiments without departing from the technical idea of the present invention, and such variations and modifications are intended to be within the scope of the invention.

What is claimed is:

1. A display panel, comprising:
a first region and a second region adjacent with each other; and
a base layer, a functional layer, and an encapsulation layer disposed in sequence, wherein the functional layer is provided with a pixel array;
wherein the pixel array in the second region is provided with two or more light transmissive areas, and portions of the encapsulation layer corresponding to at least two of the light transmissive areas are respectively provided with a lens; and
wherein a bottom surface of each of the lenses is planar and is disposed on the encapsulation layer, and an upper surface of each of the lenses is an outwardly convex curved surface.

2. The display panel according to claim 1, wherein the display panel is an active matrix organic light emitting diode (AMOLED) display panel, and the functional layer is a light emitting layer.

3. The display panel according to claim 1, wherein the light transmissive areas disposed in the pixel array are distributed in an array, a number of the lenses are corresponding to a number of the light transmissive areas, the lenses are arranged in an array, and the array of the lenses and the array of the light transmissive areas are arranged up and down.

4. The display panel according to claim 1, wherein each of the light transmissive areas is a cylindrical configuration, and the bottom surface of each of the lenses is circular, a diameter of the bottom surface of each of the lenses is equal to or greater than a diameter of a cross section of each of the light transmissive areas.

5. The display panel according to claim 1, wherein each of the lenses is made of a photoresist.

6. The display panel according to claim 5, wherein a melting point of the photoresist is less than 80 degrees.

7. The display panel according to claim 1, further comprising a touch-controlling layer disposed on the encapsulation layer, wherein each of the lenses is disposed on an insulation layer of the touch-controlling layer.

8. The display panel according to claim 1, further comprising a light-filtering layer disposed on the encapsulation layer, wherein each of the lenses is disposed on a planarization layer of the light-filtering layer.

9. A method of manufacturing the display panel according to claim 1, comprising:
providing a base layer, providing a functional layer and an encapsulation layer on the base layer, wherein the functional layer is provided with a pixel array, and the pixel array is provided with two or more light transmissive areas;
coating a photoresist on portions of the encapsulation layer corresponding to at least two of the light transmissive areas, wherein the coated photoresist is subjected to ultraviolet exposure and development to obtain a cylindrical photoresist layer; and
heating the cylindrical photoresist layer to a molten state, wherein a liquid surface tension of the cylindrical photoresist layer transforms a surface cylindrical structure of the cylindrical photoresist layer into a smooth spherical crown structure of the cylindrical photoresist layer to form each of the lenses.

10. A terminal device, comprising:
a body;
the display panel according to claim 1, wherein the display panel is disposed on the body; and
a photosensitive device disposed on the body below a second region of the display panel.
